(19) United States
(12) Patent Application Publication
(10) Pub. No.: US 2026/0239910 A1
(43) Pub. Date: Aug. 13, 2026

(54) SUBSTRATE PROCESSING METHOD AND METHOD OF FABRICATING A SEMICONDUCTOR DEVICE USING THE SAME

(71) Applicant: Samsung Electronics Co., Ltd., Suwon-si (KR)

(72) Inventors: Seunghwan SEO, Suwon-si (KR); SANG-KUK KIM, Suwon-si (KR); DUK-WON RYU, Suwon-si (KR); HYUNCHUL YOON, Suwon-si (KR)

(21) Appl. No.: 19/320,488

(22) Filed: Sep. 5, 2025

(30) Foreign Application Priority Data
Feb. 7, 2025 (KR) 10-2025-0015734

(51) Int. Cl. H01L 21/02; H01L 21/3213; H10D 30/01

(52) U.S. Cl. CPC H10P 70/27; H10D 30/025; H10P 50/267

(57) ABSTRACT

A substrate processing method may include performing a first cleaning process in a substrate processing system and performing a second cleaning process in the substrate processing system after the first cleaning process. The first cleaning process may include removing a first indium compound from the substrate processing system, and the second cleaning process may include removing a second indium compound from the substrate processing system. The first indium compound may be different from the second indium compound.

### CROSS-REFERENCE TO RELATED APPLICATIONS

This U.S. non-provisional patent application claims priority under 35 U.S.C. § 119 to Korean Patent Application No. 10-2025-0015734, filed on Feb. 7, 2025, in the Korean Intellectual Property Office, the entire contents of which are hereby incorporated by reference.

### BACKGROUND OF THE INVENTION

The present disclosure relates to a substrate processing method and a method of fabricating a semiconductor device using the same, and in particular, to a substrate processing method including an efficient cleaning process and a method of fabricating a semiconductor device using the same.

A semiconductor device is fabricated through various processes. For example, the semiconductor device may be fabricated through lithography, etching, and deposition processes, which are performed on a semiconductor wafer (e.g., a silicon wafer). Various fluidic materials are used in these semiconductor fabrication processes. Plasma may be used in the etching process and/or the deposition process. During the semiconductor fabrication process, an electrode may be used to generate and control plasma. In addition, a cleaning process may be performed to maintain a substrate processing system, in which the semiconductor fabrication process is performed, in a desired state.

### SUMMARY

An embodiment of the inventive concept provides a substrate processing method for an efficient cleaning process and a method of fabricating a semiconductor device using the same.

An embodiment of the inventive concept provides a substrate processing method, which is used to remove a metal oxide layer and its by-products, and a method of fabricating a semiconductor device using the same.

According to an embodiment of the inventive concept, a substrate processing method may include performing a first cleaning process in a substrate processing system, the first cleaning process including removing a first indium compound from the substrate processing system, and performing a second cleaning process in the substrate processing system after the first cleaning process, the second cleaning process including removing a second indium compound from the substrate processing system. The first indium compound may be different from the second indium compound.

According to an embodiment of the inventive concept, a method of fabricating a semiconductor device may include forming mold insulating patterns on a substrate, forming a channel layer to cover the mold insulating patterns, etching the channel layer thereby forming a channel pattern, and performing a cleaning process, the forming of the channel pattern. The channel layer may be formed of or include indium, and the forming of the channel pattern may include forming an indium compound. The performing of the cleaning process may include removing the indium compound, such as indium by-products.

According to other embodiments, provided herein are semiconductor devices fabricated by the present methods.

### BRIEF DESCRIPTION OF THE DRAWINGS

FIG. 1 is a flow chart illustrating a substrate processing method according to an embodiment of the inventive concept.

FIGS. 2 to 7 are diagrams illustrating a substrate processing method according to an embodiment of the inventive concept.

FIGS. 8 to 21B are diagrams illustrating a method of fabricating a semiconductor device, according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their descriptions will be omitted.

Items described in the singular herein may be provided in plural, as can be seen, for example, in the drawings. Thus, the description of a single item that is provided in plural should be understood to be applicable to the remaining plurality of items unless context indicates otherwise.

Throughout the specification, when a component is described as “including” or “comprising” a particular element or group of elements, or other forms of the words “include” or “comprise”, it is to be understood that the component is formed of only the element or the group of elements, or the element or group of elements may be combined with additional elements to form the component, unless the context indicates otherwise.

The terms “same,” and “coplanar,” as used herein when referring to steps, orientation, layout, location, shape, or other measures do not necessarily mean an exactly identical steps, orientation, layout, location, shape, or other measure, but are intended to encompass nearly identical steps, orientation, layout, location, shape or other measures within typical variations that may occur resulting from conventional manufacturing processes. The term “substantially” may be used herein to emphasize this meaning with respect to these and other terms, unless the context or other statements indicate otherwise. For example, items described as “substantially the same,” may be exactly the same, or constant, or may be the same or constant within acceptable variations that may occur, for example, due to manufacturing processes.

It will be understood that when an element is referred to as being “connected” to or “on” another element, it can be directly connected to or on the other element or intervening elements may be present. In contrast, when an element is referred to as “contacting” or “in contact with” another element (or using any form of the word “contact”), there are no intervening elements present at the point of contact. As used herein, items described as being “electrically connected” are configured such that an electrical signal can be passed from one item to the other.

As used herein the terms “on” or “cover” are intended to mean that an element is over another element. The elements may be touching or not. For example, there may be layers between layers that are “on” one another or that “cover” one another. An element “on” or that “covers” another element need not cover an entire top surface of an element below to be considered “on” or “covering”. The terms are intended to encompass one element “on” or that “covers” all, or any part of, an element below it.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere without an ordinal number or with a different ordinal number (e.g., “second” in the specification or another claim).

Spatially relative terms, such as “below,” “lower,” “upper,” “top,” “bottom,” and the like, may be used herein for ease of description to describe positional relationships, such as illustrated in the figures, for example. It will be understood that the spatially relative terms encompass different orientations of the device in addition to the orientation depicted in the

### FIGURES

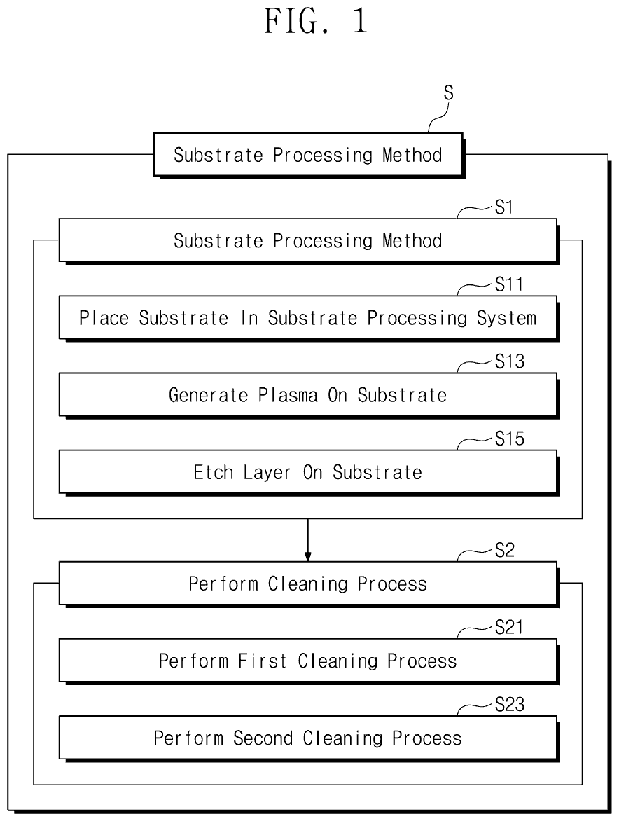

FIG. 1 is a flow chart illustrating a substrate processing method according to an embodiment of the inventive concept.

Referring to FIG. 1, a substrate processing method S may be provided. The substrate processing method S may be used to process a substrate using a substrate processing system, which will be described below. In the present specification, the term of “substrate” may mean a semiconductor wafer. The semiconductor wafer may be a silicon-containing wafer, but the inventive concept is not limited to this example.

The substrate processing method S may include performing an etching process (in S1) and performing a cleaning process (in S2). The etching process (in S1) may include placing a substrate in the substrate processing system (in S11), generating plasma on the substrate (in S13), and etching a metal oxide layer on the substrate (in S15). The cleaning process (in S2) may include performing a first cleaning process (in S21) and performing a second cleaning process (in S23). According to example embodiments, each of the first cleaning process and the second cleaning process comprises generating plasma in the substrate processing system.

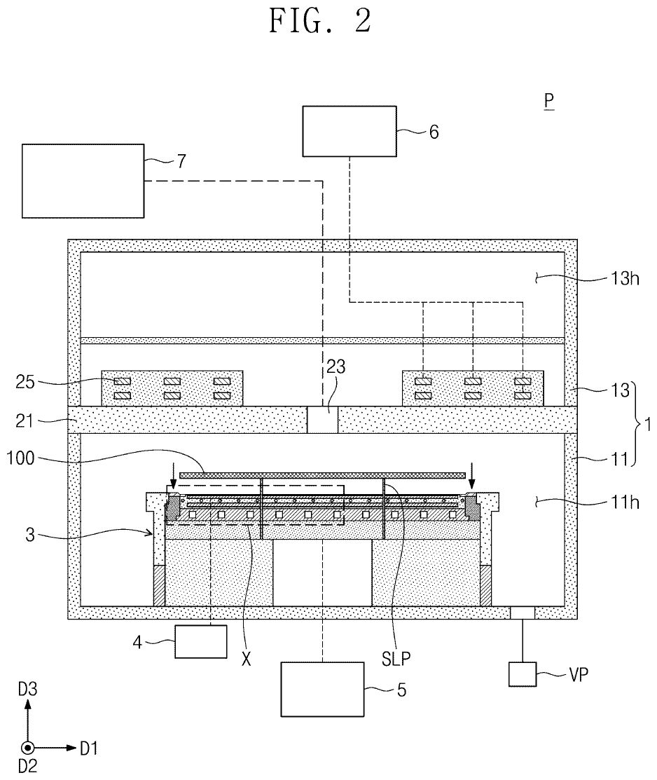

Hereinafter, the substrate processing method S of FIG. 1 will be described in more detail with reference to FIGS. 2 to 7.

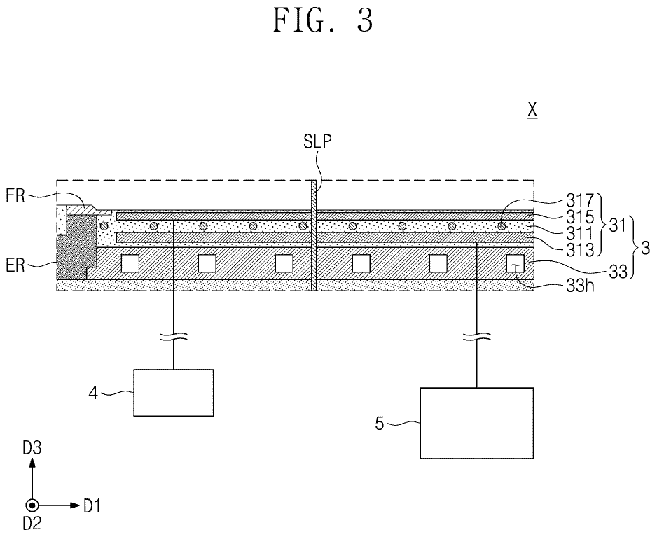

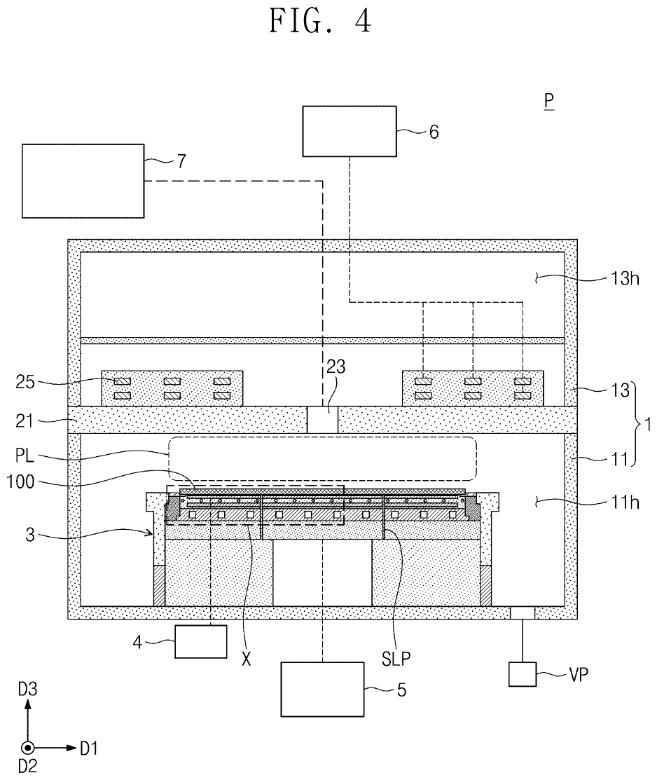

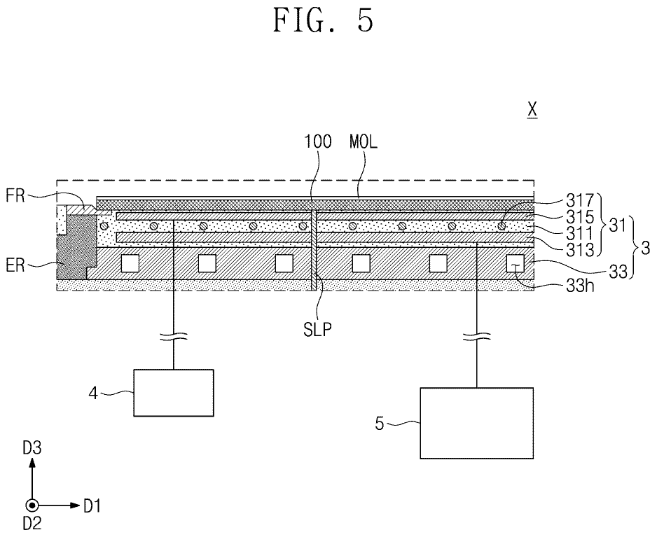

FIGS. 2 to 7 are diagrams illustrating a substrate processing method according to an embodiment of the inventive concept. FIGS. 2, 4, 6, and 7 are sectional views illustrating a substrate processing system according to an embodiment of the inventive concept. FIG. 3 is an enlarged sectional view of a portion X of FIG. 2, and FIG. 5 is an enlarged sectional view of a portion X of FIG. 4.

Referring to FIGS. 1, 2, and 3, the placing of the substrate in the substrate processing system (in S11) may include placing a substrate 100 on substrate lift pins SLP, lowering the substrate lift pins SLP to place the substrate 100 on a stage 3, and fastening the substrate 100.

According to an embodiment of the inventive concept, a substrate processing system P may perform an etching process on the substrate 100. For example, the substrate processing system P may be a plasma etching system. More specifically, the substrate processing system P may generate plasma using an induction current. For example, the substrate processing system P may be an inductively coupled plasma (ICP) system. However, the inventive concept is not limited to this example, and the substrate processing system P may perform a deposition process on the substrate 100.

The substrate processing system P may include a process chamber 1, a plasma generating part, a stage 3, substrate lift pins SLP, a DC power generating device 4, a first RF power generating device 5, a second RF power generating device 6, a gas supplying device 7, and a vacuum pump VP.

The process chamber 1 may include a lower chamber 11 and an upper chamber 13 on the lower chamber 11. The lower chamber 11 may have a process space 11h. An etching process on the substrate 100 may be performed in the process space 11h. When the etching process is performed on the substrate 100, the process space 11h may be in a vacuum state or a substantially vacuum state. The upper chamber 13 may have an upper space 13h. The plasma generating part may be placed in the upper space 13h. The upper space 13h may be maintained at atmospheric pressure, unlike the process space 11h.

The plasma generating part may include a plasma window 21, a gas divider 23, and an antenna ring 25. The plasma window 21 may be placed between the lower chamber 11 and the upper chamber 13 to separate the process space 11h and the upper space 13h from each other. The gas divider 23 may be placed in the plasma window 21 and may be connected to the gas supplying device 7. The gas divider 23 may uniformly supply a reaction gas or the like into the process space 11h. The antenna ring 25 may be placed on the plasma window 21 and may include a plurality of concentric parts. The antenna ring 25 may be connected to the second RF power generating device 6.

The stage 3 may be disposed in the lower chamber 11 and may include a cooling plate 33 and a chuck 31 on the cooling plate 33. The chuck 31 may include a chuck body 311, a plasma electrode 313, a chuck electrode 315, and a heater 317. In addition, the substrate lift pins SLP may be provided in the stage 3.

The substrate lift pins SLP may be connected to a driving part and may be movable in a vertical direction. The substrate 100 may be loaded on or unloaded from the stage 3 by the substrate lift pins SLP. For example, when the substrate lift pins SLP are elevated, the substrate 100 may be placed on the substrate lift pins SLP to have a top surface parallel to a first direction D1 and a second direction D2. Next, by lowering the substrate lift pins SLP, the substrate 100 may be placed on the stage 3.

In the present specification, according to example embodiments, the first and second directions D1 and D2 may not be parallel to each other and may be parallel to the top surface of the substrate 100. A third direction D3 may interest the first and second directions D1 and D2, and may not be parallel to the first and second directions D1 and D2. The third direction D3 may be for example, perpendicular to the top surface of the substrate 100. The first and second directions D1 and D2 may be referred to as horizontal directions, and the third direction D3 may be referred to as a vertical direction. For example, the first direction D1, the second direction D2, and the third direction D3 may be orthogonal to each other.

The chuck body 311 may be in contact with the substrate 100. When viewed in a plan view, a focus ring FR and an edge ring ER may be provided to enclose the chuck body 311. The plasma electrode 313 may be placed within the chuck body 311 and may be connected to the first RF power generating device 5. In the chuck body 311, the chuck electrode 315 may be placed on the plasma electrode 313. The chuck electrode 315 may be connected to the DC power generating device 4 and may receive a DC power from the DC power generating device 4. The substrate 100 may be fastened by the DC power applied to the chuck electrode 315. For example, the substrate 100 may be fastened to the stage 3 by an electrostatic force. The heater 317 may be placed in the chuck body 311 and between the chuck electrode 315 and the plasma electrode 313 and may be used to control the temperature of the substrate 100.

The cooling plate 33 may be placed below the chuck 31. The cooling plate 33 may have a cooling hole 33h. Cooling water may be provided to flow through the cooling hole 33h. The cooling water in the cooling hole 33h may absorb heat from the substrate 100. Thus, the temperature of the substrate 100 on the stage 3 may be controlled.

The gas supplying device 7 may supply a fluidic material (e.g., a process gas and a reaction gas) into the process space 11h. For example, the gas supplying device 7 may include a gas tank, a compressor, and a valve. A portion of the fluidic material, which is supplied into the process space 11h by the gas supplying device 7, may be used to generate plasma.

The vacuum pump VP may be connected to the process space 11h. The vacuum pump VP may be used to exhaust or remove the fluidic material from the process space 11h. For example, the process space 11h may be maintained in a vacuum pressure state. For example, the vacuum pump VP may include a turbomolecular pump (TMP).

Referring to FIGS. 1, 4, and 5, the generation of the plasma on the substrate (in S13) may include supplying a process gas into the substrate processing system P and applying an RF power to the antenna ring 25.

The gas supplying device 7 may be used to supply the process gas into the substrate processing system P. The process gas from the gas supplying device 7 may be uniformly supplied into the process space 11h through the gas divider 23. For example, the process gas may include or be a reaction gas (e.g., chlorine (Cl₂), hydrofluoric acid (HF), or silicon tetrachloride (SiCl₄)), but the inventive concept is not limited to this example.

The applying of the RF power to the antenna ring 25 may be performed by the second RF power generating device 6. The second RF power generating device 6 may apply an RF power to the antenna ring 25. The antenna ring 25 may produce an electric field and/or a magnetic field in the process space 11h using the RF power applied thereto. Due to the electric field and/or the magnetic field, a portion of the process gas, which is provided in the process space 11h, may form plasma PL on the stage 3.

The etching of a metal oxide layer MOL on the substrate 100 may include applying an RF power to the stage 3 and producing a first indium compound and a second indium compound. The metal oxide layer MOL on the substrate 100 may be formed by a deposition process, but the inventive concept is not limited to this example. For example, the metal oxide layer MOL may comprise indium (In). In an embodiment, the metal oxide layer MOL may further comprise at least one of gallium (Ga), zinc (Zn), titanium (Ti), and aluminum (Al).

The applying of the RF power to the stage 3 may be executed by the first RF power generating device 5. The first RF power generating device 5 may apply the RF power to the plasma electrode 313 of the stage 3. The plasma electrode 313 may be used to attract particles in the plasma toward the substrate 100 using the RF power applied thereto. Thus, at least a portion of the metal oxide layer MOL on the substrate 100 may be etched.

As a result of the etching of the metal oxide layer MOL, the first and second indium compounds, which are different from each other, may be produced. For example, both the first and second indium compounds may comprise indium (In), but they further include different elements from each other. The first and second indium compounds may be by-products, which are produced from the metal oxide layer MOL during the etching process. The first and second indium compounds may be in a solid state in the process space 11h. Thus, the first and second indium compounds may not be exhausted to the outside by the vacuum pump VP and may be left in the process space 11h. This may lead to an internal contamination issue in the substrate processing system P. For example, the first indium compound may comprise oxygen (O) (e.g. InOₓ), and the second indium compound may comprise chlorine (Cl) (e.g. InClₓ).

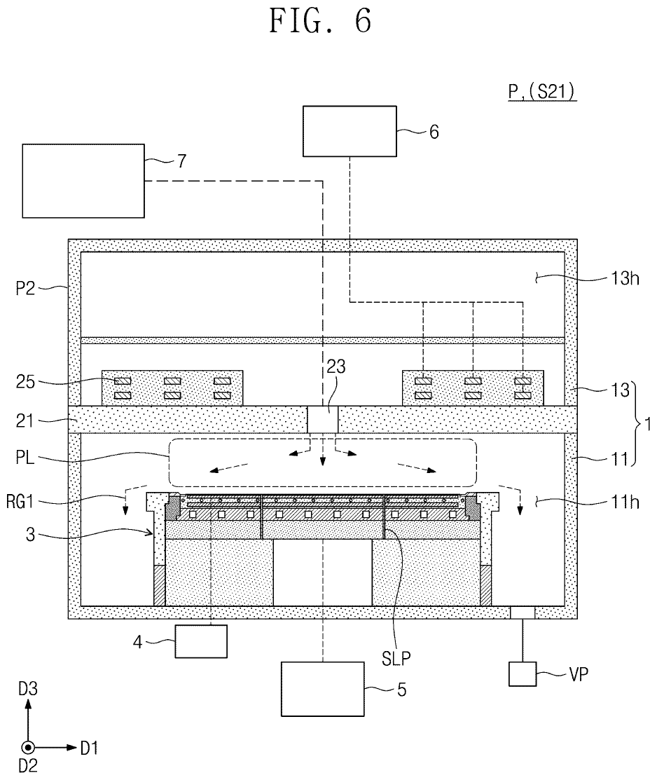

Referring to FIGS. 1 and 6, the first cleaning process (in S21) may include supplying first reaction gases RG1 into the substrate processing system P, removing the first indium compound, and generating the plasma PL in the substrate processing system P.

The supplying of the first reaction gases RG1 into the substrate processing system P may be performed by the gas supplying device 7. The gas supplying device 7 may supply the first reaction gases RG1 uniformly into the process space 11h of the lower chamber 11 through the gas divider 23. The first reaction gases RG1 may react with the first indium compound, which is left in the process space 11h.

The first indium compound may be decomposed through a chemical reaction with the first reaction gases RG1 supplied into the process space 11h. For example, the first indium compound may comprise oxygen (O), and the first reaction gases RG1 may comprise boron trichloride (BCl₃) and chlorine (Cl₂). In this example, the first indium compound may be decomposed as follows:

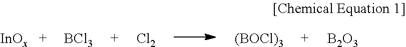

The first indium compound comprising indium and oxygen (O) (e.g. InOₓ) may be decomposed to trichloroboroxin ((BOCl)₃), and diboron trioxide (B₂O₃) through a chemical reaction with the first reaction gases RG1 comprising boron (B) and chlorine (Cl), as shown in the above chemical equation 1. The trichloroboroxin ((BOCl)₃) and the diboron trioxide (B₂O₃) may be a highly volatile property compound, compared to the first indium compound. For example, the trichloroboroxin ((BOCl)₃) and the diboron trioxide (B₂O₃) in the process space 11h may be in a gaseous state. Thus, the trichloroboroxin ((BOCl)₃) and the diboron trioxide (B₂O₃) may be easily exhausted from the substrate processing system P by the vacuum pump VP. For example, the first indium compound may be decomposed by the first reaction gases RG1 and may be exhausted or removed from the substrate processing system P.

In an embodiment, the first indium compound and the first reaction gases RG1 comprising chlorine (Cl) may react to form the second indium compound comprising indium and chlorine (Cl). For example, the first indium compound may be decomposed to form the second indium compound. For example, the second indium compound may be produced during the removal of the first indium compound in the first cleaning process.

The generation of the plasma PL in the substrate processing system P may be the same or substantially the same as the generation of the plasma PL on the substrate (in S13). The second RF power generating device 6 may apply the RF power to the antenna ring 25, and the antenna ring 25 may produce the plasma PL on the substrate 100. For example, the plasma PL may be formed on the substrate 100 by the second RF power generating device 6. The plasma PL may expedite a reaction between the first indium compound and the first reaction gases RG1. Thus, the first indium compound may be easily decomposed.

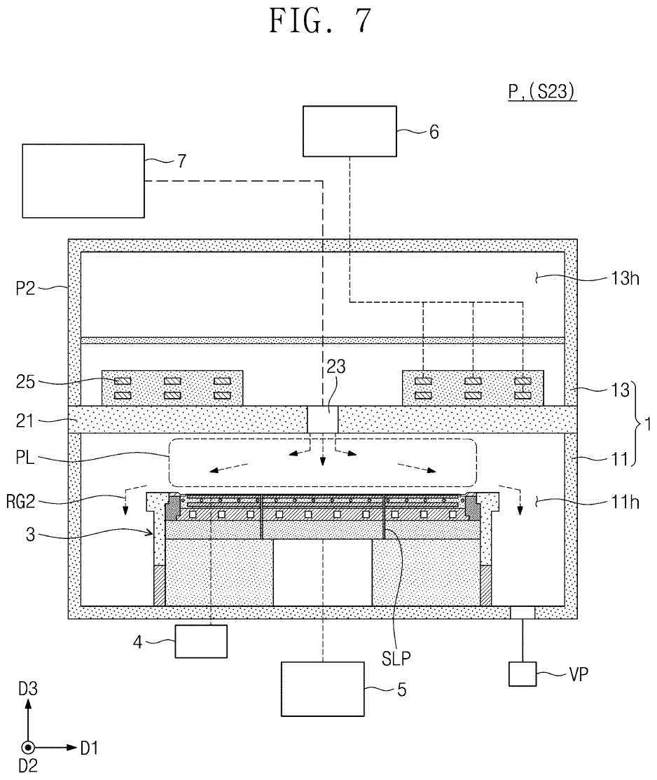

Referring to FIGS. 1 and 7, the second cleaning process (in S23) may include supplying second reaction gases RG2 into the substrate processing system P, removing the second indium compound, and generating the plasma PL in the substrate processing system P.

The supplying of the second reaction gases RG2 into the substrate processing system P may be performed by the gas supplying device 7. The gas supplying device 7 may supply the second reaction gases RG2 uniformly into the process space 11h of the lower chamber 11 through the gas divider 23. The second reaction gases RG2 may react with the second indium compound, which is left in the process space 11h.

The second indium compound may be decomposed through a chemical reaction with the second reaction gases RG2 supplied into the process space 11h. For example, the second indium compound may comprise chlorine (Cl), and the second reaction gases RG2 may comprise hydrogen bromide (HBr), methane (CH₄), and hydrogen (H₂). In this example, the second indium compound may be decomposed as follows:

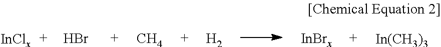

The second indium compound comprising indium and chlorine (Cl) (such as InClₓ) may be decomposed to indium bromide (InBrₓ) and trimethylindium (In(CH₃)₃) through a reaction with the second reaction gases RG2 comprising bromine (Br), hydrogen (H), and carbon (C). Indium bromide (InBrₓ) and trimethylindium (In(CH₃)₃) may have a lower boiling point than the second indium compound. Thus, indium bromide (InBrₓ) and trimethylindium (In(CH₃)₃) in the process space 11h may be in a gaseous state. Thus, indium bromide (InBrₓ) and trimethylindium (In(CH₃)₃) may be easily exhausted from the substrate processing system P by the vacuum pump VP. For example, the second indium compound may be decomposed by the second reaction gases RG2 and may be exhausted or removed from the substrate processing system P.

In an embodiment, the supplying of the second reaction gases RG2 into the substrate processing system P may include supplying some of the second reaction gases RG2 into the substrate processing system P. For example, only methane (CH₄) and hydrogen (H₂) of the second reaction gases RG2 may be supplied into the process space 11h. Alternatively, only hydrogen bromide (HBr) of the second reaction gases RG2 may be supplied into the process space 11h. In this example, the second indium compound may react with the second reaction gases RG2 to form only one of indium bromide (InBrₓ) and trimethylindium (In(CH₃)₃).

In an embodiment, the second cleaning process (in S23) may include a plurality of process steps. For example, the second cleaning process (in S23) may include supplying some of the second reaction gases RG2 into the substrate processing system P and supplying the others of the second reaction gases RG2 into the substrate processing system P. For example, among the second reaction gases RG2, methane (CH₄) and hydrogen (H₂) gases may be supplied into the process space 11h, and then, the second reaction gases RG2 (e.g., hydrogen bromide (HBr)) may be supplied into the process space 11h. In addition, hydrogen bromide (HBr) of the second reaction gases RG2 may first be supplied into the process space 11h and then methane (CH₄) and hydrogen (H₂) may be supplied into the process space 11h.

The generation of the plasma PL in the substrate processing system P may be the same or substantially the same as the generation of the plasma PL on the substrate 100 in the first cleaning process. The plasma PL may be formed on the substrate 100 by the second RF power generating device 6. Due to the plasma PL, the second indium compound may react with the second reaction gases RG2 easily. Thus, the second indium compound may be easily decomposed and may be removed from the substrate processing system P.

In an embodiment, each of the first and second cleaning processes may be performed in the substrate processing system P, which is used for the etching process, and may be performed using a gaseous material, not a liquid material. For example, each of the first and second cleaning processes may be an in-situ dry cleaning (ISD) process.

According to an embodiment of the inventive concept, the substrate processing method S may include performing a cleaning process to remove by-products formed by the etching process. In example embodiments where an indium-containing metal oxide layer is etched through the etching process, an indium compound may be produced as by-products. The cleaning process may prevent a contamination issue, which may occur in the substrate processing system P by the indium compound. Thus, it may be possible to increase the maintenance interval of the substrate processing system P. In this example, the productivity of the semiconductor device may be increased.

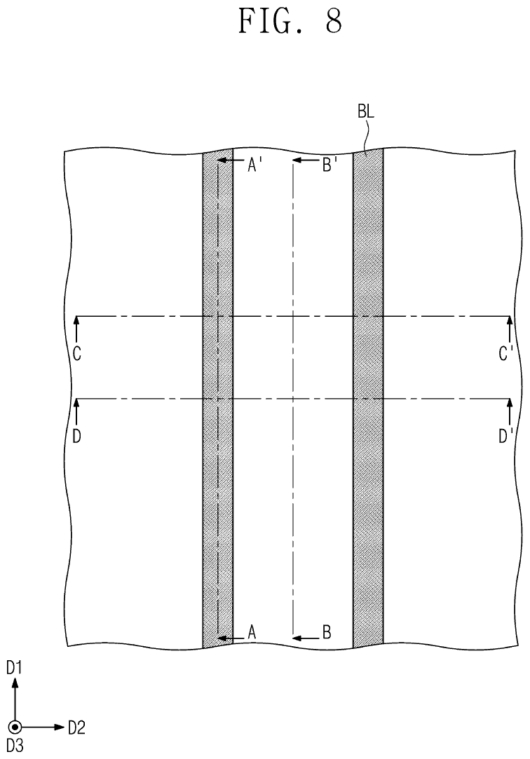

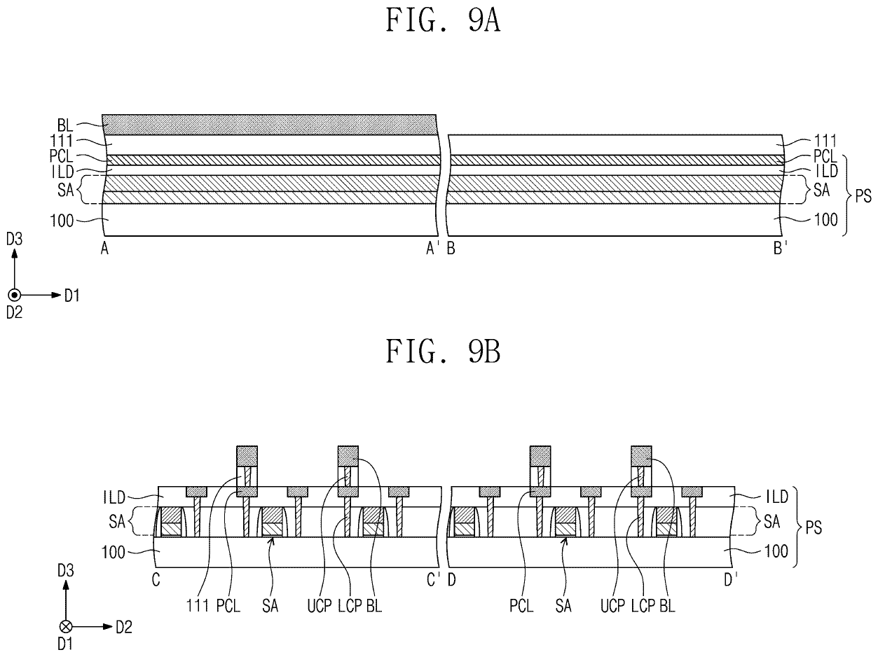

FIGS. 8 to 21B are diagrams illustrating a method of fabricating a semiconductor device, according to an example embodiment of the inventive concept. FIGS. 8, 10, 12, 14, 16, 18, and 20 are plan views illustrating a semiconductor device according to an embodiment of the inventive concept. FIGS. 9A, 9B, 11A, 11B, 13A, 13B, 15A, 15B, 17A, 17B, 19A, 19B, 21A, and 21B are sectional views taken along lines A-A′, B-B′, C-C′, and D-D′ of FIGS. 8, 10, 12, 14, 16, 18, and 20.

Referring to FIGS. 8, 9A, and 9B, a peripheral circuit structure PS including core circuits SA may be formed on the substrate 100.

In detail, a lower insulating layer ILD may be formed on the substrate 100 to cover the core circuits SA. For example, the lower insulating layer ILD may be formed of or include at least one of silicon oxide, silicon nitride, silicon oxynitride, and low-k dielectric materials. The lower insulating layer ILD may have a single layer or may have a multi-layered structure including two or more different materials.

In an embodiment, circuit interconnection lines PLC and the lower contact plugs LCP, which are connected to each other, may be formed in the lower insulating layer ILD. The circuit interconnection lines PLC may be electrically connected to the core circuits SA through the lower contact plugs LCP.

Bit lines BL may be formed on the lower insulating layer ILD. The formation of the bit lines BL may include forming a first interlayer insulating layer on the lower insulating layer ILD, forming the lower contact plugs LCP to penetrate the first interlayer insulating layer, depositing a lower conductive layer on the first interlayer insulating layer, and patterning the lower conductive layer and the first interlayer insulating layer. Accordingly, the bit lines BL and a first interlayer insulating pattern 111 may be formed from the lower conductive layer and the first interlayer insulating layer, respectively. Furthermore, the lower insulating layer ILD may be partially exposed to the outside.

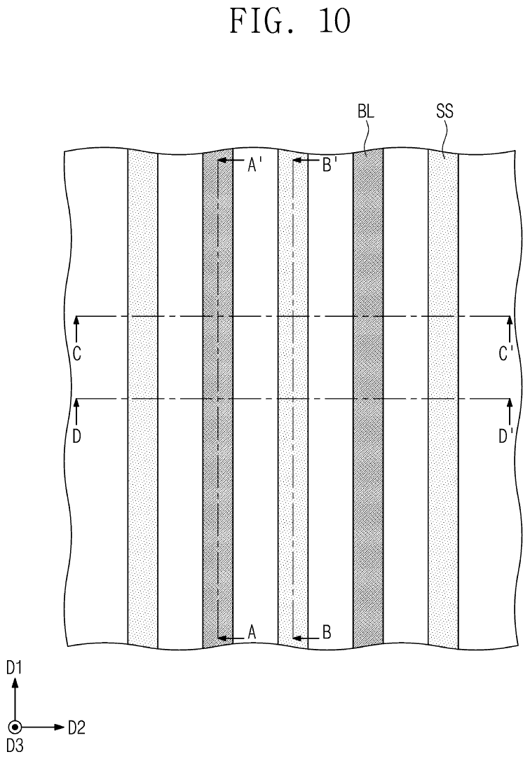

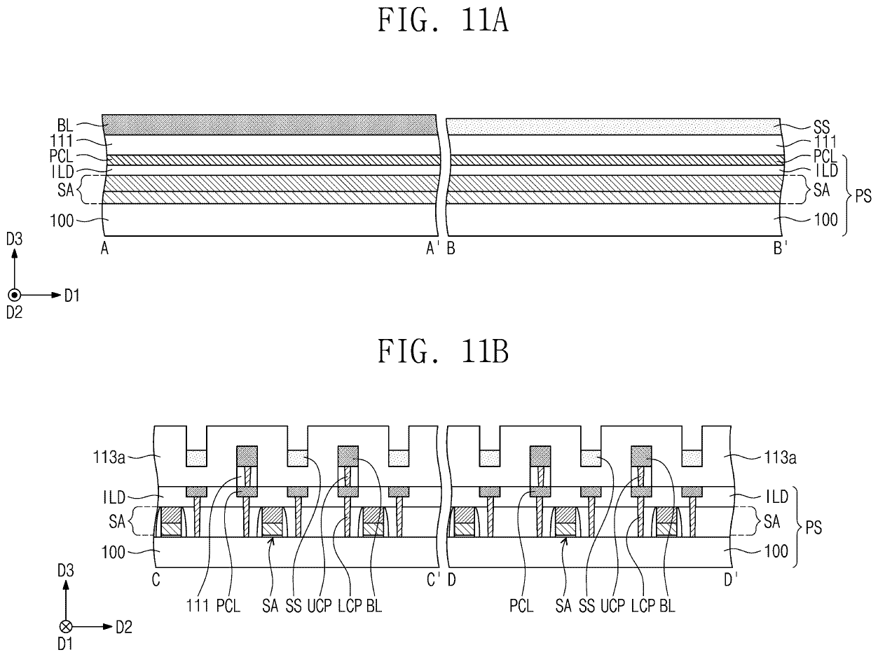

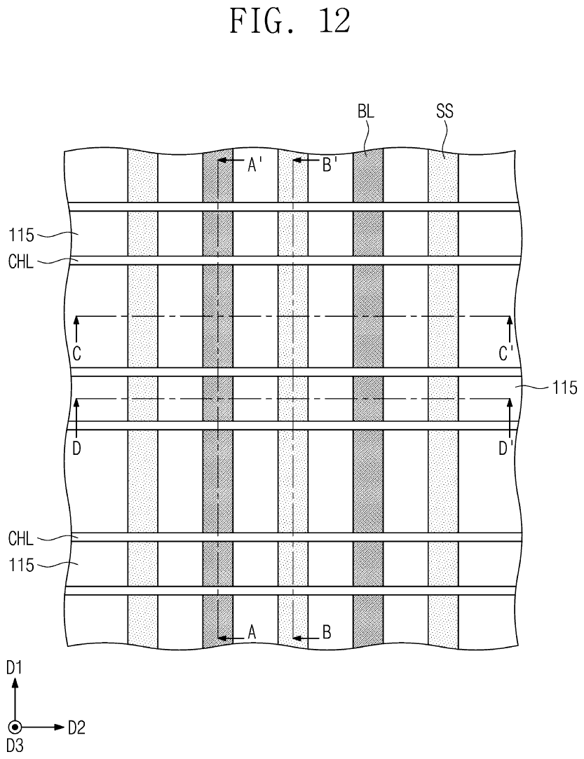

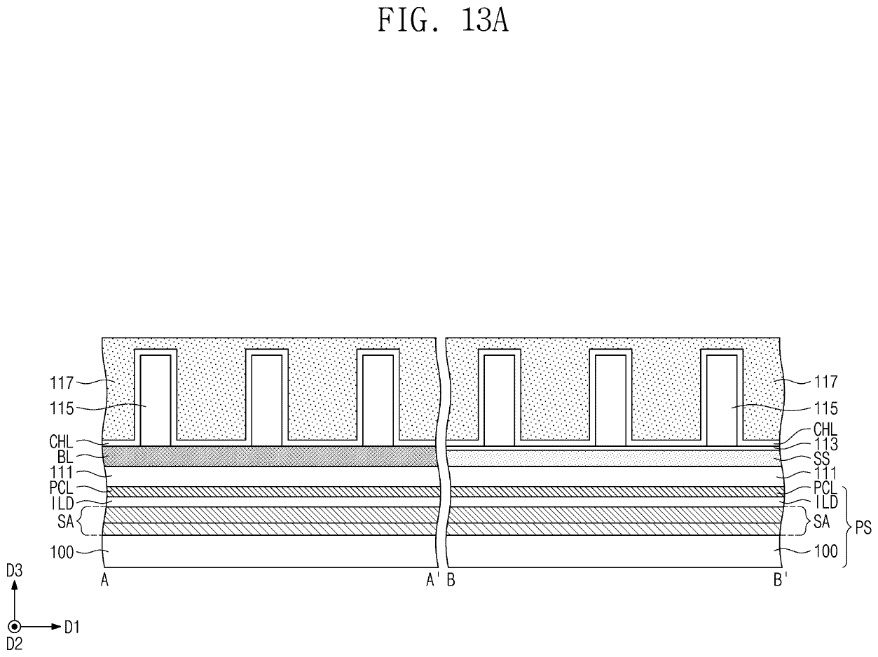

Referring to FIGS. 10, 11A, and 11B, a second interlayer insulating layer 113a may be formed on the lower insulating layer ILD. The second interlayer insulating layer 113a may cover a top surface of the lower insulating layer ILD and the bit lines BL with a uniform thickness. The thickness of the second interlayer insulating layer 113a may be smaller than half a distance between adjacent ones of the bit lines BL. Accordingly, the second interlayer insulating layer 113a may define gap regions between adjacent ones of the bit lines BL. Each of the gap regions may be extended parallel to the bit lines BL and in the first direction D1. Vacuum, air or other gases may fill the “gap regions.” A “gap” may still exist between two elements even when the gap is filled,

Thereafter, shielding structures SS may be formed to fill the gap regions of the second interlayer insulating layer 113a. Each of the shielding structures SS may be placed between adjacent ones of the bit lines BL. The formation of the shielding structures SS may include forming a shielding layer on the second interlayer insulating layer 113a to fill the gap regions and recessing a top surface of the shielding layer. For example, the shielding structures SS may be formed of or include at least one metallic material (e.g., W, Ti, Ni, and Co) or a conductive two-dimensional (2D) material (e.g., graphene).

For example, the formation of the shielding structures SS may be omitted. In this example, a space between adjacent ones of the bit lines BL may be filled with the second interlayer insulating layer 113a. However, the inventive concept is not limited to this example.

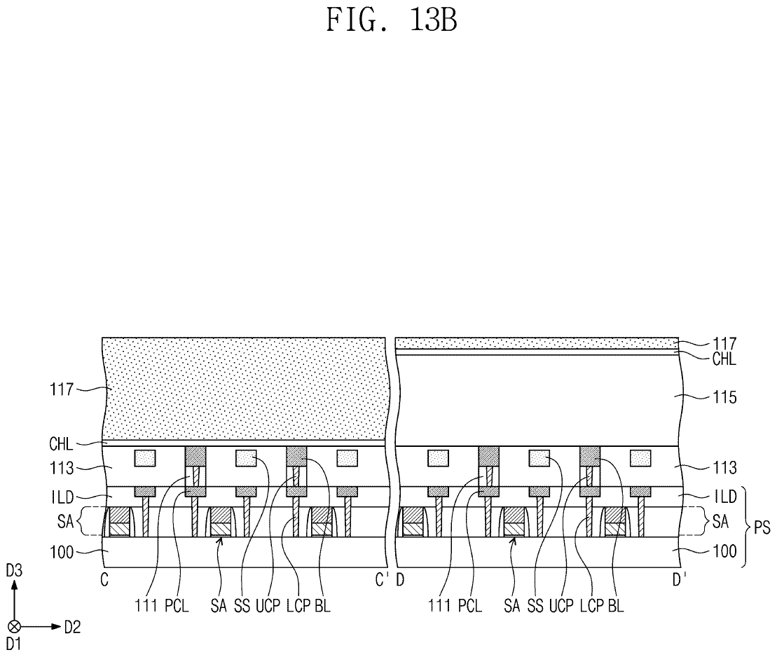

Referring to FIGS. 12, 13A, and 13B, a second interlayer insulating pattern 113 may be formed on the lower insulating layer ILD. The formation of the second interlayer insulating pattern 113 may include depositing an insulating material on the second interlayer insulating layer 113a and the shielding structures SS and performing a planarization process on the insulating material and the second interlayer insulating layer 113a. As a result of the planarization process, top surfaces of the bit lines BL may be exposed. Top surfaces of the shielding structures SS may not be exposed, unlike the bit lines BL.

Next, mold insulating patterns 115 may be formed on the second interlayer insulating pattern 113 and the bit lines BL. The mold insulating patterns 115 may be extended in the second direction D2 and may be spaced apart from each other in the first direction D1. The mold insulating patterns 115 may be formed to partially expose the bit lines BL. For example, the mold insulating patterns 115 may include a material having an etch selectivity with respect to the second interlayer insulating pattern 113, but the inventive concept is not limited to this example.

A channel layer CHL may be formed to cover the mold insulating patterns 115. The channel layer CHL may be formed to have a uniform thickness. The channel layer CHL may be formed using deposition processes such as physical vapor deposition (PVD), thermal chemical vapor deposition (thermal CVD), low-pressure chemical vapor deposition (LP-CVD), plasma enhanced chemical vapor deposition (PE-CVD), and atomic layer deposition (ALD). The channel layer CHL may be extended from the mold insulating patterns 115 to a region on top surfaces of the bit lines BL and the second interlayer insulating pattern 113. For example, the channel layer CHL may be easily formed by performing a deposition process on a patterned structure. Thus, the structure of the semiconductor device may be changed within the scope of the present application.

The channel layer CHL may comprise indium (In) and may further comprise at least one of gallium (Ga), zinc (Zn), titanium (Ti), and aluminum (Al). For example, the channel layer CHL may be formed of or include at least one of indium oxide (InO), indium gallium zinc Oxide (IGZO), indium aluminum tin oxide (IATO), indium tin zinc oxide (ITZO), and indium tin oxide (ITO). The channel layer CHL may correspond to the metal oxide layer on the substrate, described with reference to FIGS. 1 to 7.

A sacrificial layer 117 may be formed to cover the channel layer CHL. The sacrificial layer 117 may fill a space between the mold insulating patterns 115. The formation of the sacrificial layer 117 may include performing a planarization process on the sacrificial layer 117. Thus, the sacrificial layer 117 may be for example, a flat top surface or a substantially flat top surface. The sacrificial layer 117 may be formed of or include a material having an etch selectivity with respect to the mold insulating patterns 115. For example, the sacrificial layer 117 may be formed of or include at least one of insulating materials, which are formed using a spin-on-glass (SOG) method, or silicon oxide.

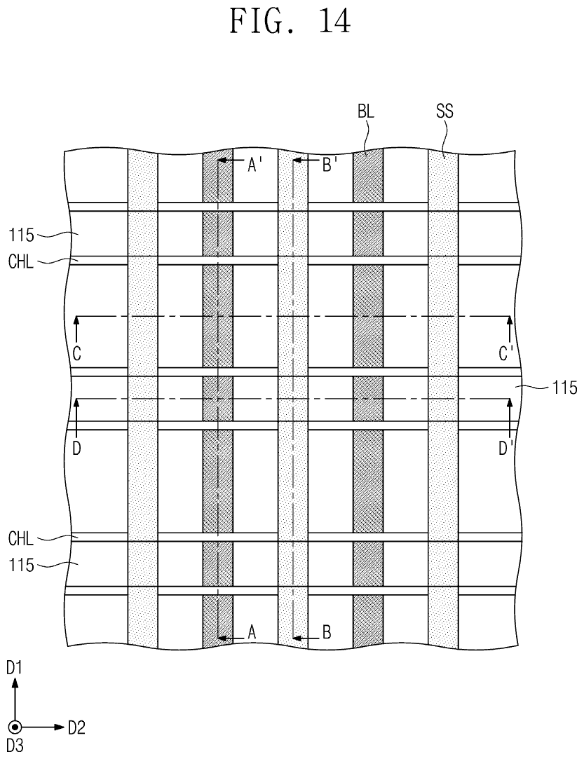

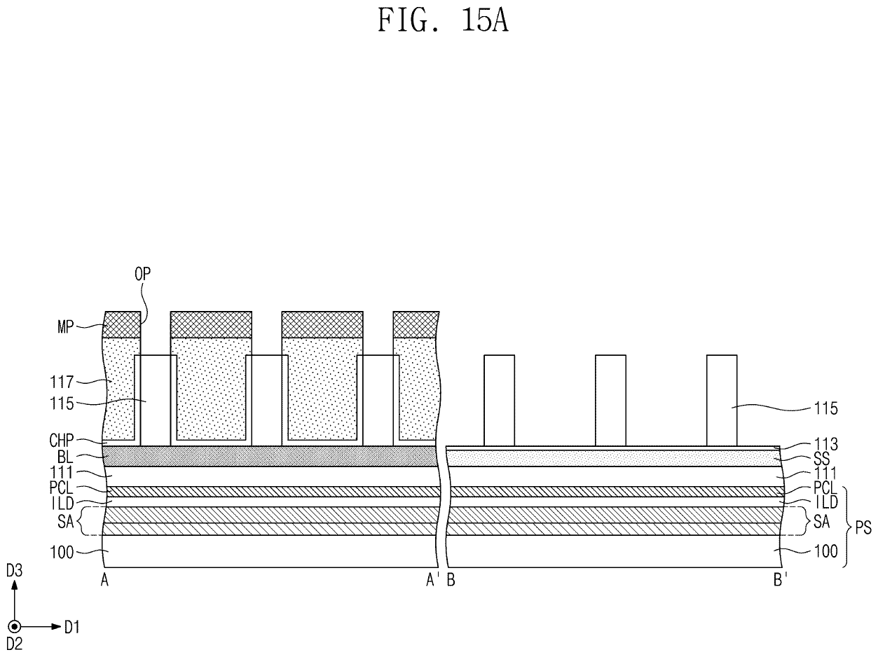

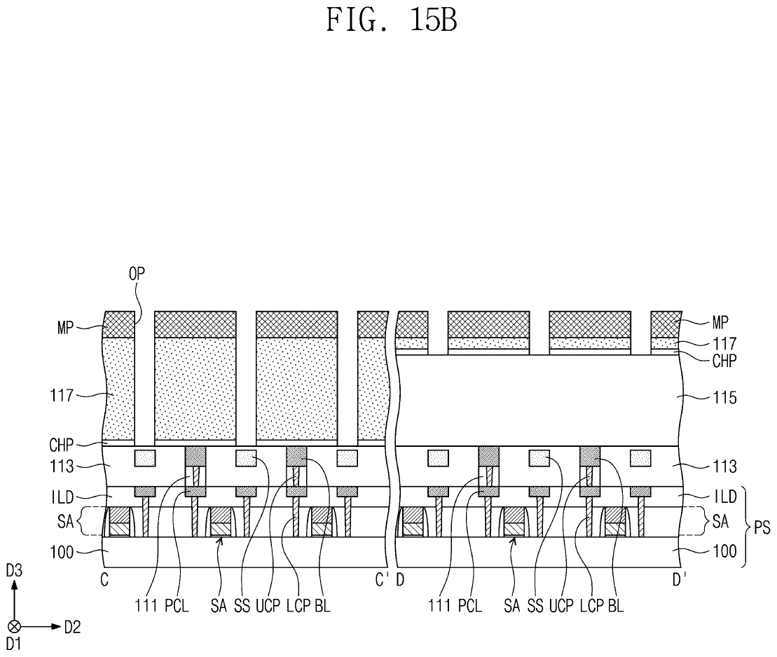

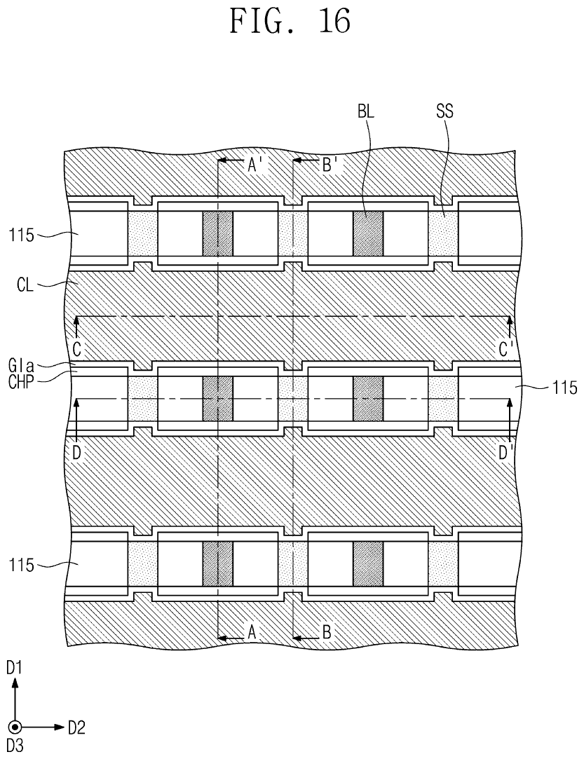

Referring to FIGS. 14, 15A, and 15B, a mask pattern MP may be formed on the sacrificial layer 117. The mask pattern MP may have openings OP. The openings OP of the mask pattern MP may be spaced apart from each other in the first and second directions D1 and D2. An etching process using the mask pattern MP may be performed after the formation of the mask pattern MP. The sacrificial layer 117 and/or the channel layer CHL may be partially removed as a result of the etching process. Accordingly, a portion of the second interlayer insulating pattern 113 and portions of the mold insulating patterns 115 may be exposed. In addition, as a result of the partial removal of the channel layer CHL, channel patterns CHP may be formed from the channel layer CHL.

Each of the channel patterns CHP may include a horizontal portion, which is extended along a top surface of the bit line BL, and vertical portions, which are extended from the horizontal portion to side surfaces of the mold insulating pattern 115.

At least a portion of each of the channel patterns CHP may extend vertically with respect to a top surface of the substrate. According to non-limiting examples, at least a portion of each of the channel patterns CHP may extend in a direction (e.g., the third direction D3) that may be perpendicular to the top surface of the substrate 100. For example, the semiconductor device may include a vertical channel transistor (VCT). However, the inventive concept is not limited to this example.

In an embodiment, the sacrificial layer 117 may be partially removed, and then, the channel layer CHL may be partially removed. For example, the sacrificial layer 117 and the channel layer CHL may be etched through different processes. In an embodiment, the sacrificial layer 117 and the channel layer CHL may be partially removed at the same time. For example, the sacrificial layer 117 and the channel layer CHL may be etched by the same process, or substantially the same process.

Because the channel layer CHL comprises indium (In), indium oxide may be produced during a process of etching the channel layer CHL. For example, the formation of the channel patterns CHP may include producing an indium compound. In this example, a cleaning process of removing the indium compound may be performed after the formation of the channel patterns CHP.

In an embodiment, the channel patterns CHP may be formed using the substrate processing method S described with reference to FIGS. 1 to 7. The formation of the channel patterns CHP may include producing the first and second indium compounds. In addition, the first cleaning process of removing the first indium compound and the second cleaning process of removing the second indium compound may be performed, after the formation of the channel patterns CHP. In an example embodiment, the second cleaning process may be performed after the first cleaning process.

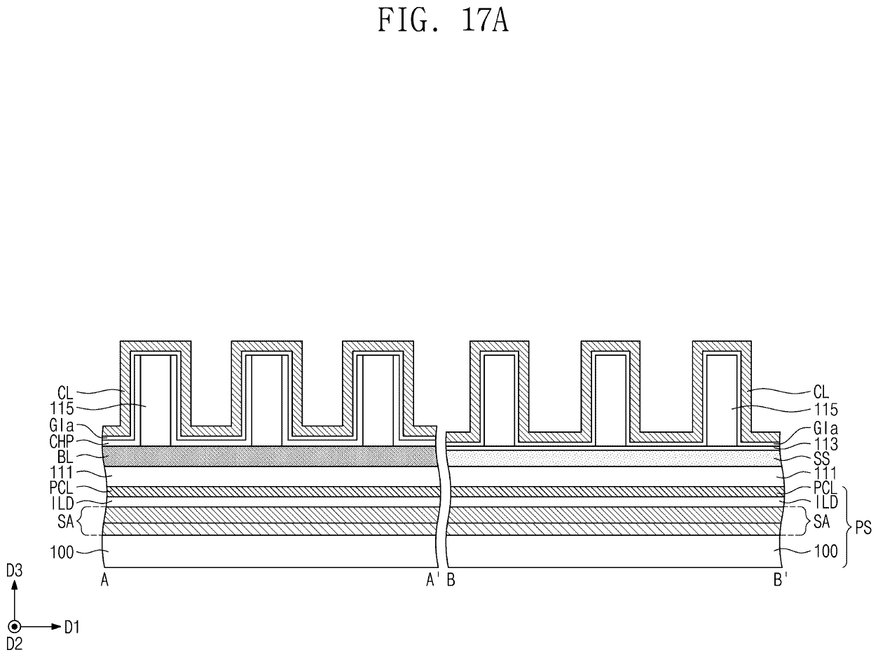

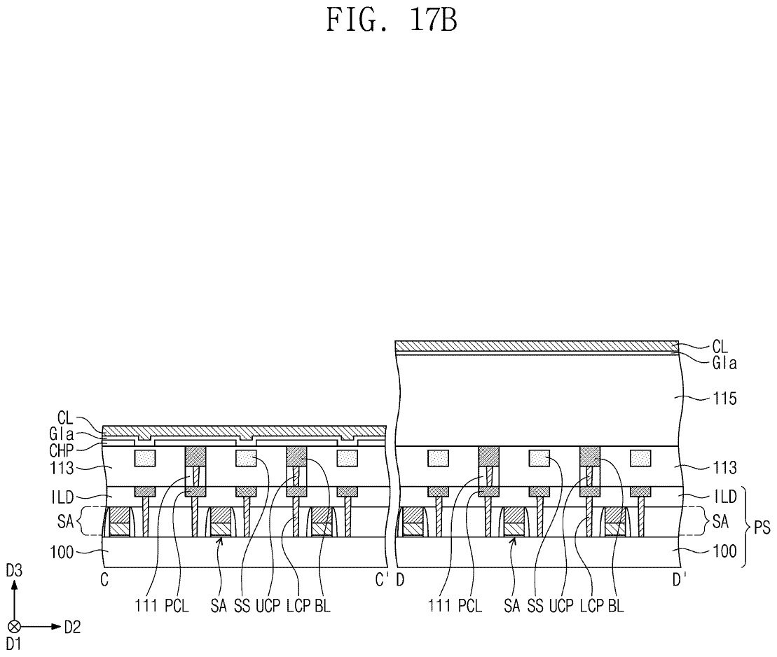

Referring to FIGS. 16, 17A, and 17B, the mask pattern MP and the sacrificial layer 117 may be removed. The sacrificial layer 117 may be selectively removed using an etching process, which is performed with an etch selectivity with respect to the mold insulating patterns 115 and the channel patterns CHP. Thus, the channel patterns CHP may be exposed.

A preliminary gate insulating layer GIa and a gate conductive layer CL may be sequentially formed on the mold insulating patterns 115 and the channel patterns CHP. The preliminary gate insulating layer GIa may cover the channel patterns CHP and the mold insulating patterns 115 with a uniform thickness. The gate conductive layer CL may cover the preliminary gate insulating layer Gia with a uniform thickness. The thickness of the gate conductive layer CL may be larger than the thickness of the preliminary gate insulating layer GIa. For example, each of the preliminary gate insulating layer GIa and the gate conductive layer CL may be formed using a deposition process.

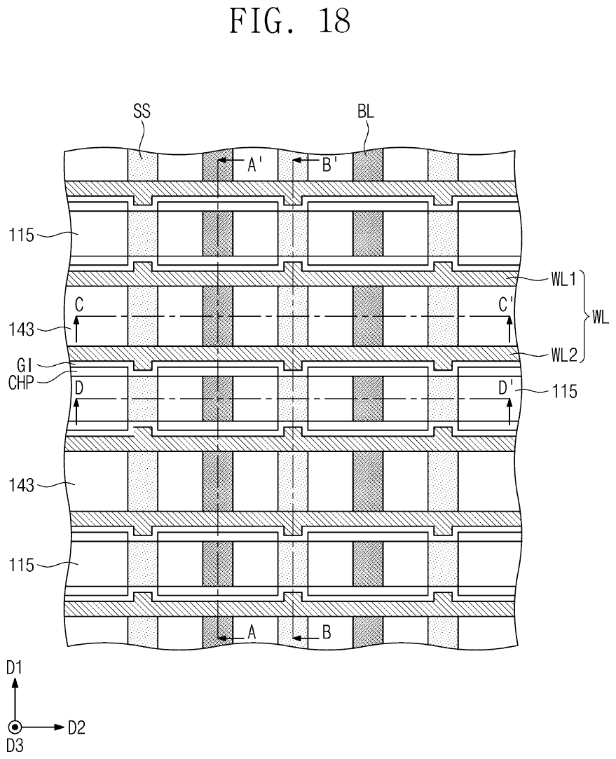

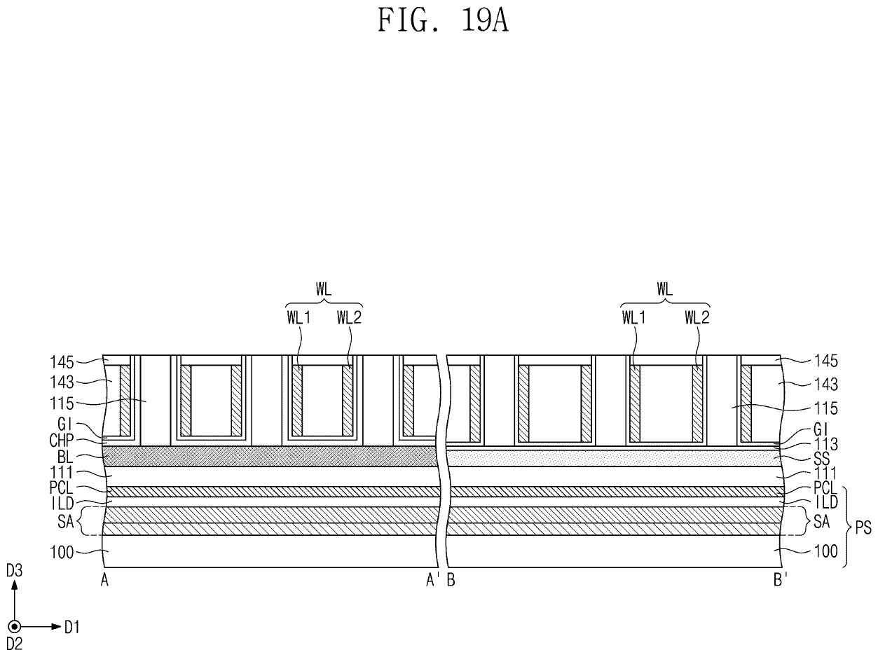

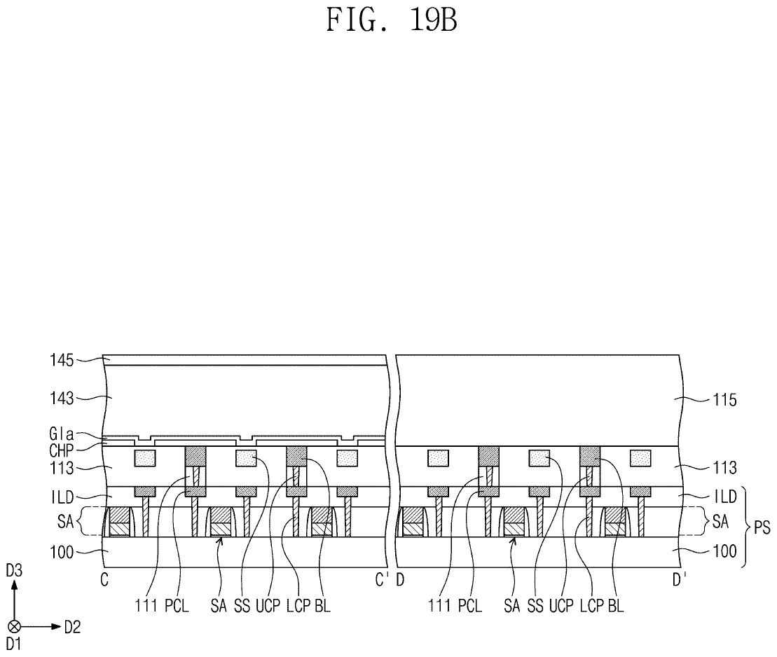

Referring to FIGS. 18, 19A, and 19B, word lines WL including first and second word lines WL1 and WL2 may be formed. The first and second word lines WL1 and WL2 may be formed by performing an anisotropic etching process on the gate conductive layer CL. The anisotropic etching process may be performed such that top surfaces of the first and second word lines WL1 and WL2 are lower than top surfaces of the channel patterns CP.

Next, first insulating patterns 143 may be respectively formed between corresponding pairs of the first and second word lines WL1 and WL2. Each of the first insulating patterns 143 may fill a space between each pair of the first and second word lines WL1 and WL2. Top surfaces of the first insulating patterns 143 may be coplanar with the top surfaces of the first and second word lines WL1 and WL2.

Capping patterns 145 may be formed on the first insulating patterns 143. The formation of the capping patterns 145 may include performing a planarization process to expose top surfaces of the mold insulating patterns 115. The top surfaces of the capping patterns 145 may be coplanar with the top surfaces of the channel patterns CP and the top surfaces of the mold insulating patterns 115.

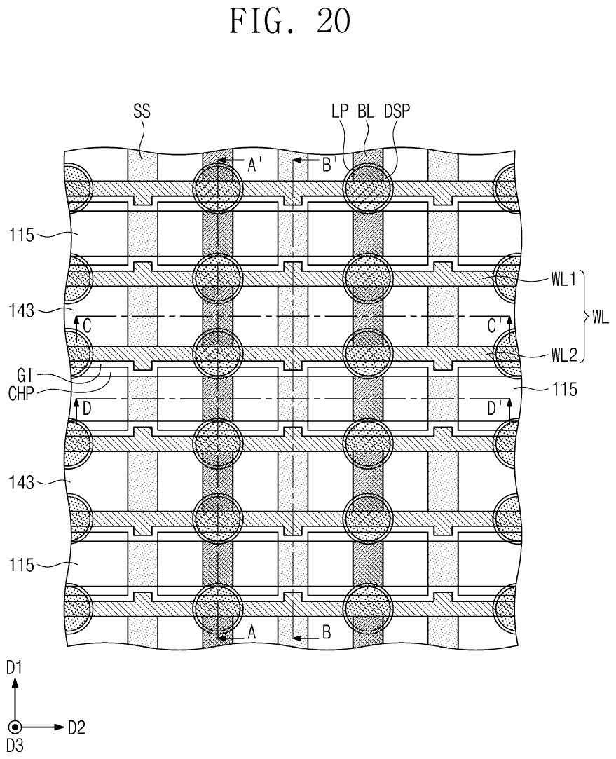

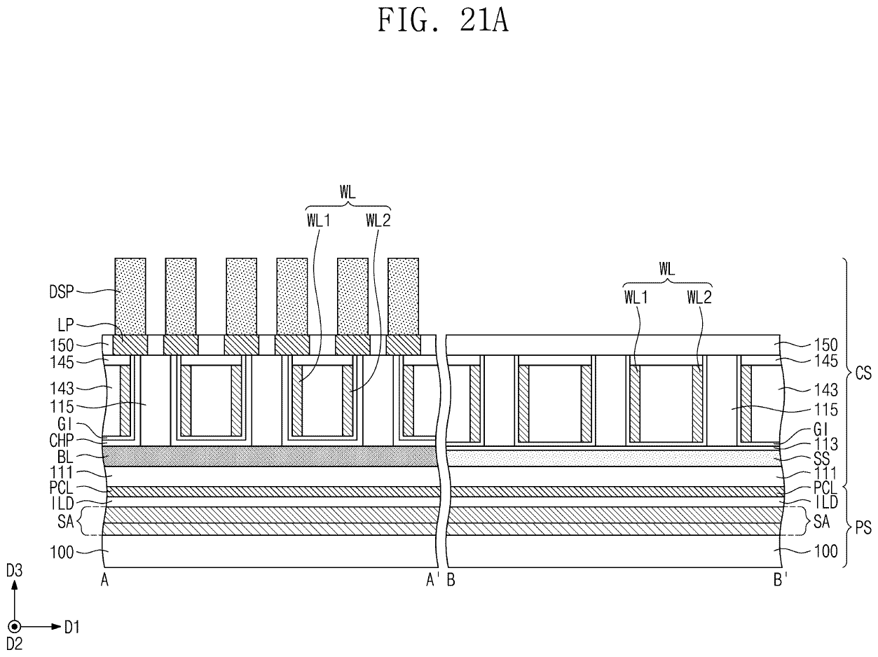

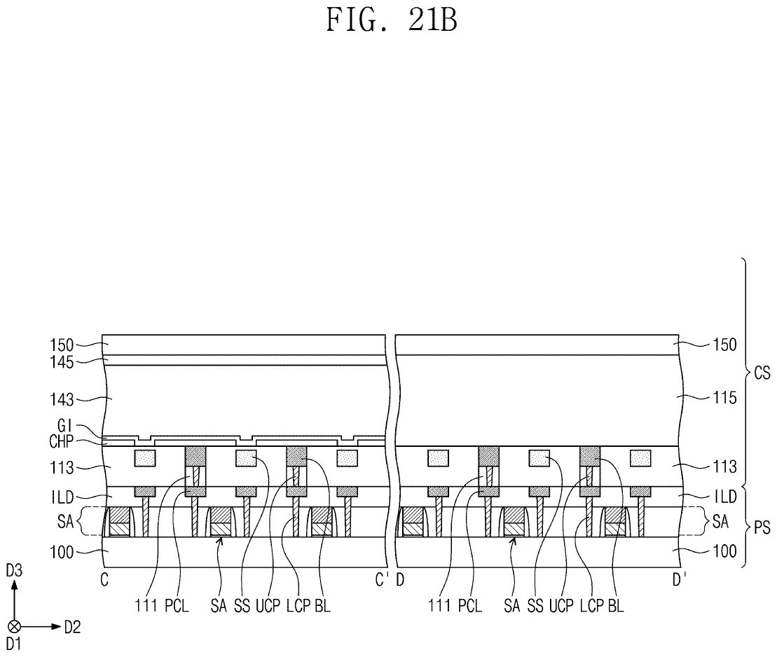

Referring to FIGS. 20, 21A, and 21B, landing pads LP and second insulating patterns 150 may be formed on the capping patterns 145 and the mold insulating patterns 115. The landing pads LP may be spaced apart from each other in the first and second directions D1 and D2. The landing pads LP may each be connected to a corresponding channel pattern CHP. The second insulating patterns 150 may be formed to fill a space between the landing pads LP. The landing pads LP and the second insulating patterns 150 may have top surfaces that are coplanar or substantially coplanar with each other.

Data storage patterns DSP may be formed on corresponding landing pads LP. The data storage patterns DSP may be connected to the landing pads LP and may be electrically connected to the channel patterns CHP through the landing pads LP. Thus, a cell array structure CS including the bit lines BL, the channel patterns CHP, the word lines WL, and the data storage patterns DSP may be formed on the peripheral circuit structure PS.

In an embodiment, each of the data storage patterns DSP may be a capacitor including a bottom electrode, a dielectric layer, and a top electrode. In this example, the semiconductor device may be a dynamic random access memory (DRAM) device. In an embodiment, the data storage patterns DSP may include a magnetic tunnel junction pattern. In this example, the semiconductor device may be a magnetic random access memory (MRAM) device. In an embodiment, the data storage patterns DSP may include a phase-change material or a variable resistance material. In this example, the semiconductor device may be a phase-change random access memory (PRAM) device or a resistive random access memory (ReRAM) device. However, the inventive concept is not limited to this example, and the data storage patterns DSP may include various structures and various materials, which are configured to store data.

The semiconductor device may be a semiconductor chip (i.e., a semiconductor device singulated from (e.g., cut from) a wafer).

According to an embodiment of the inventive concept, a substrate processing method may include performing a cleaning process to remove by-products formed by an etching process. In this example, where an indium-containing metal oxide layer is etched through the etching process, an indium compound may be produced as by-products. The cleaning process may prevent a contamination issue, which may occur in the substrate processing system by the indium compound. Thus, by cleaning, it may be possible to increase the maintenance interval of the substrate processing system. In this example, the productivity of the semiconductor device may be increased.

While example embodiments of the inventive concept have been particularly shown and described, it will be understood by one of ordinary skill in the art that variations in form and detail may be made therein without departing from the spirit and scope of the attached claims.

What is claimed is:

1. A substrate processing method, comprising:
performing a first cleaning process in a substrate processing system, the first cleaning process comprising removing a first indium compound from the substrate processing system; and
performing a second cleaning process in the substrate processing system, after the first cleaning process, the second cleaning process comprising removing a second indium compound from the substrate processing system
wherein the first indium compound is different from the second indium compound.

2. The substrate processing method of claim 1, further comprising performing an etching process in the substrate processing system, before performing the first cleaning process.

3. The substrate processing method of claim 2, wherein the etching process etches a metal oxide layer comprising indium, on a substrate.

4. The substrate processing method of claim 1, wherein each of the first cleaning process and the second cleaning process comprises generating plasma in the substrate processing system.

5. The substrate processing method of claim 1, wherein the first cleaning process comprises supplying a first reaction gas into the substrate processing system, and
wherein the second cleaning process comprises supplying a second reaction gas into the substrate processing system.

6. The substrate processing method of claim 5, wherein the first reaction gas comprises boron trichloride and chlorine, and
wherein the first indium compound comprises indium and oxygen.

7. The substrate processing method of claim 5, wherein the second reaction gas comprises at least one reaction gas selected from the group consisting of hydrogen bromide, methane, and hydrogen, and
wherein the second indium compound comprises indium and chlorine.

8. The substrate processing method of claim 1, wherein each of the first cleaning process and the second cleaning process is an in-situ dry cleaning process performed in the substrate processing system.

9. A method of fabricating a semiconductor device, comprising:
forming mold insulating patterns on a substrate;
forming a channel layer covering the mold insulating patterns;
etching the channel layer, thereby forming a channel pattern; and
performing a cleaning process after the forming of the channel pattern,
wherein the channel layer comprises indium,
wherein the forming of the channel pattern comprises forming an indium compound, and
wherein the performing of the cleaning process comprises removing the indium compound.

10. The method of claim 9, wherein the performing of the cleaning process comprises generating plasma on the substrate.

11. The method of claim 9, wherein the indium compound comprises indium and at least one of oxygen and chlorine.

12. The method of claim 9, wherein the cleaning process comprises performing a first cleaning process and performing a second cleaning process after the first cleaning process.

13. The method of claim 12, wherein the performing of the first cleaning process removes the indium compound by generating plasma on the substrate and supplying a first reaction gas to the substrate, wherein the first reaction gas comprises boron trichloride and chlorine.

14. The method of claim 12, wherein the performing of the second cleaning process removes the indium compound by generating plasma on the substrate and supplying second reaction gas to the substrate, wherein the second reaction gas comprises at least one of hydrogen bromide, methane, and hydrogen.

15. The method of claim 9, wherein the channel layer further comprises at least one of gallium, zinc, titanium, and aluminum.

16. The method of claim 9, wherein at least a portion of the channel pattern extends vertically with respect to a top surface of the substrate.

17. The method of claim 16, wherein at least a portion of the channel pattern extends in a direction perpendicular to the top surface of the substrate.

18. The method of claim 9, wherein the forming of the channel layer is performed using a deposition process.

19. The method of claim 9, further comprising forming a data storage pattern on the channel pattern.

20. A semiconductor device fabricated by the method of claim 9.
